(19) United States
(12) Patent Application Publication
(10) Pub. No.: US 2024/0179832 A1
(43) Pub. Date: May 30, 2024

(54) MULTI-ENTRY SOCKET POWER DELIVERY STRUCTURE AND BACKPLATE

(71) Applicants: Phil Geng, Washougal, WA (US); Xiaoning Ye, Portland, OR (US); Yipeng Zhong, Shanghai (CN); Meng Wang, Shanghai (CN); Hongfei Yan, Mesa, AZ (US); Chuansheng Liu, Shanghai (CN); Lejie Liu, Portland, OR (US); Mohanraj Prabhugoud, Portland, OR (US); Fernando Gonzalez Lenero, Zapopan (MX); Dongwang Chen, Shanghai (CN); Sanjoy Saha, Portland, OR (US); Ralph Miele, Hillsboro, OR (US); Baris Bicen, Chandler, AZ (US); David Shia, Portland, OR (US); Jeffory Smalley, Olympia, WA (US); Eric Erike, Mesa, AZ (US)

(72) Inventors: Phil Geng, Washougal, WA (US); Xiaoning Ye, Portland, OR (US); Yipeng Zhong, Shanghai (CN); Meng Wang, Shanghai (CN); Hongfei Yan, Mesa, AZ (US); Chuansheng Liu, Shanghai (CN); Lejie Liu, Portland, OR (US); Mohanraj Prabhugoud, Portland, OR (US); Fernando Gonzalez Lenero, Zapopan (MX); Dongwang Chen, Shanghai (CN); Sanjoy Saha, Portland, OR (US); Ralph Miele, Hillsboro, OR (US); Baris Bicen, Chandler, AZ (US); David Shia, Portland, OR (US); Jeffory Smalley, Olympia, WA (US); Eric Erike, Mesa, AZ (US)

(21) Appl. No.: 18/435,821

(22) Filed: Feb. 7, 2024

(30) Foreign Application Priority Data
Jan. 25, 2024 (WO) PCT/CN2024/074050

(51) Int. Cl. H05K 1/02

(52) U.S. Cl. CPC H05K 1/0263; H05K 2201/10189; H05K 2201/2009

(57) ABSTRACT

A multi-entry socket power delivery structure is attachable to a printed circuit board to provide improved delivery of one or more power supply signals to a socket. The power delivery structure provides an additional path for power supply signals to be delivered to a socket (in addition to the “power corridor” of the printed circuit board). The power delivery structure comprises one or more portions, with individual portions comprising a printed circuit board connection portion that attaches to the printed circuit board to receive a power supply signal generated by a voltage regulator, and a socket connection portion that attaches to the printed circuit board to deliver the power supply signal to the socket via the printed circuit board. The power delivery structure can be located in the recess of a reinforced backplate that provides structural integrity to a processor stack and associated thermal management solution loading mechanism.

This application claims the benefit under 35 U.S.C. § 119(a) of international patent application PCT/CN2024/074050, filed on Jan. 25, 2024, and entitled, “MULTI-ENTRY SOCKET POWER DELIVERY STRUCTURE AND BACKPLATE.”

### BACKGROUND

Voltage regulators can provide power supply signals to a socketed integrated circuit component via a “power corridor” in the printed circuit board on which the voltage regulators and socket are located. The power corridor of a printed circuit board typically comprises interconnect layers dedicated to the delivery of power signals from the voltage regulators to the socket.

### BRIEF DESCRIPTION OF THE DRAWINGS

FIG. 1 illustrates a perspective exploded view of an example apparatus comprising a multi-entry socket power delivery structure and reinforced backplate.

FIGS. 2A-2C illustrate top, bottom, and cross-sectional views, respectively of an example multi-entry socket power delivery structure attached to an example printed circuit board.

FIG. 3 is a perspective view of an example dual-entry socket power delivery structure.

FIG. 4A is a front perspective view of an example backplate.

FIG. 4B is a front perspective view of the example multi-entry socket power delivery structure of FIG. 3 positioned on the surface of the example backplate of FIG. 4A.

FIG. 4C illustrates a back perspective view of the example multi-entry socket power delivery structure of FIG. 3 located in the example backplate of FIG. 4A.

FIG. 5 is a front perspective view of a multi-entry socket power delivery structure located on a backplate comprising a bridge between portions of the multi-entry socket power delivery structure.

FIG. 6 is a cross-sectional view of an example backplate with reinforcement features located on front and back surfaces of the backplate.

FIG. 7 is a block diagram of an example computing system in which the multi-entry socket power delivery structures and backplates described herein may be implemented.

### DETAILED DESCRIPTION

The current demanded by high-performance integrated circuit components (in particular, high-end server processors) has increased over time as more functionality and performance are packed into integrated circuit components to meet customer demands. Supplying these increasing amounts of currents to integrated circuit components typically involves some combination of adding more power pins to integrated circuit components and sockets and increasing the thickness and/or the number of metal layers in the printed circuit board that delivers the current from voltage regulators to the power pins of an integrated circuit component socket.

Disclosed herein are multi-entry socket power delivery structures (also referred to herein as “multi-entry power delivery structures” or “power delivery structures”) that provide improved power signal delivery (current delivery) to an integrated circuit component socket. Reinforced backplates are also disclosed herein that accommodate the multi-entry power delivery structures and provide structural reliability to integrated circuit components, thermal management solutions, and thermal management solution loading mechanisms. Reinforced backplates can also aid in ensuring robust electrical connections between socket pins in a land grid array (LGA socket) and an integrated circuit component, which can ensure that the socketed integrated circuit component performs as expected. The power delivery structures disclosed herein are referred to as “multi-entry” structures as they provide for the entry of multiple power signals (e.g., VDD, VDDQ) to a socket. Separate voltage regulators can generate different power signals. The power delivery structures disclosed herein are attached to the back surface of a printed circuit board and improve the delivery of power signals to socket power by providing an additional path (in addition to the printed circuit board power corridor) for current to flow from the voltage regulators to the socket. The power delivery structures comprise multiple portions that are positioned in recesses or grooves on the surface of a backplate that helps secure the power delivery structure to a printed circuit board. The backplate is reinforced to provide structural reliability to the socket, an integrated circuit component attached to the socket, a thermal management solution attached to the integrated circuit component, and the thermal management solution loading mechanism that secures the thermal management solution to the integrated circuit component. Backplate reinforcements can take the form of thicker regions of the backplate or a reinforcement structure that fits within recesses on a backplate surface.

The multi-entry socket power delivery structure and backplate technologies disclosed herein have at least the following advantages. First, the use of multi-entry socket power delivery structures to deliver power signals from voltage regulators to a socket can provide a low-resistance path for the power signals in addition to the printed circuit board power corridor (the interconnect layers of a printed circuit board dedicated to delivering power to the socket). The power delivery structures disclosed herein can thus alleviate or even remove the power delivery bottleneck presented by the printed circuit board. Second, the number of interconnect layers and/or the thicknesses of interconnect layers in the printed circuit board power corridor can be reduced, which can result in lower printed circuit board costs. Third, the low-resistance path offered by the power delivery structures disclosed herein can result in improved energy efficiency due to reduced power signal power loss. Fourth, reduced ohmic heating in the printed circuit board due to less power supply current being delivered via the printed circuit board may reduce printed circuit board temperature during integrated circuit component operation, which can result in lower temperatures at the socket power pins. This may enable a greater current to be handled by the individual socket power pins, which may allow for fewer socket power pins to be used in a particular socket design. This may result in a more efficient printed circuit board design due to having to route power supply signals to fewer socket pins. Fifth, the power delivery structures disclosed herein can be attached to the backside of printed circuit board via existing surface mount technologies and thus do not require additional manufacturing process development.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a surface that is substantially planar can include surfaces that comprise some dishing, bumps, imperfections, or other non-planar features resulting from processing variations and/or limitations. Values modified by the word “about” include values within +/−10% of the listed values and values listed as being within a range include those within a range from 10% less than the listed lower range limit and 10% greater than the listed higher range limit.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, component, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, field effect transistor (FET)) or a passive electronic component (e.g., resistor, inductor, capacitor).

As used herein, the term “thermally conductively coupled” refers to layers or components that are coupled to facilitate the flow of heat between them. For example, a thermal management solution can be thermally conductive coupled to an integrated circuit component by a layer of thermal interface material positioned between the thermal management solution and the integrated circuit component.

As used herein, the phrase “electrically conductively coupled” refers to layers or components that are coupled to facilitate the flow of electrical current between them. For example, a socket or a voltage regulator located on a surface of a printed circuit board can be electrically conductively coupled to a multi-entry socket power delivery structure located on an opposing surface of the printed circuit board by a plurality of interconnect traces and a plurality of vias in the printed circuit board.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

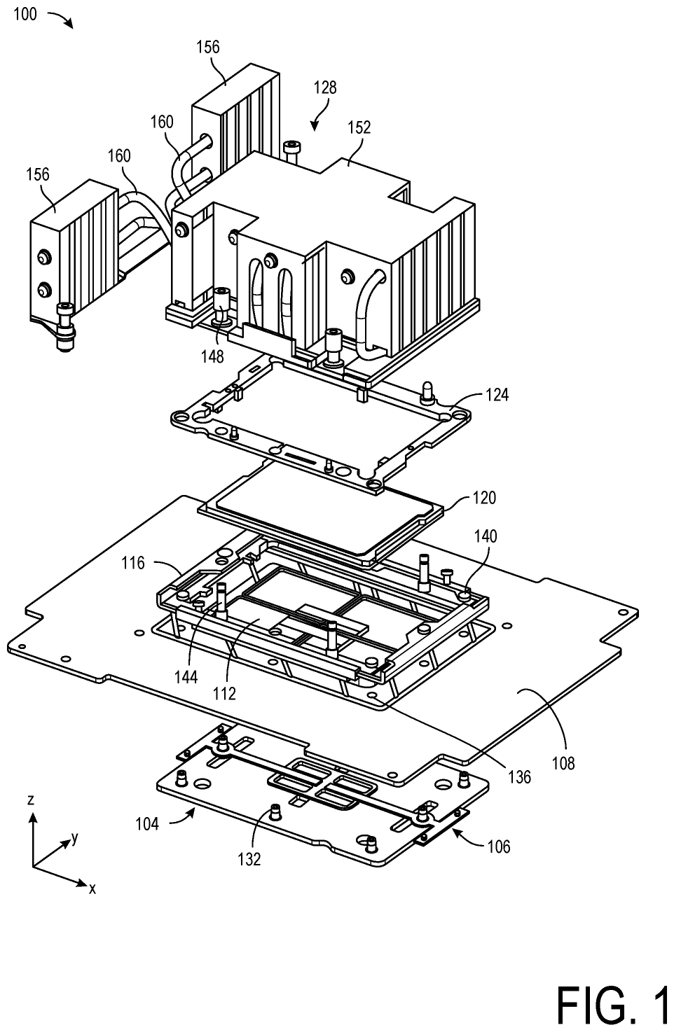

FIG. 1 illustrates an exploded perspective view of an example apparatus comprising a multi-entry socket power delivery structure and reinforced backplate. The apparatus 100 is an example apparatus in which a multi-entry socket power delivery structure and backplate provide improved power signal delivery to a socket and structural reliability to a processor stack (integrated circuit component and attached thermal management solution) and thermal management solution loading mechanism (the loading mechanism used to secure the thermal management solution to the socketed integrated circuit component). The apparatus 100 comprises a backplate 104, a multi-entry socket power delivery structure 106, a printed circuit board 108, a land grid array (LGA) socket 112, a bolster plate 116, an integrated circuit component 120, a carrier 124, and a thermal management solution 128. The backplate 104 can be any of the reinforced backplates disclosed herein and accommodates the multi-entry socket power delivery structure 106. The power delivery structure 106 assists in delivering multiple power signals from voltage regulators or other power signal generation circuitry (not shown in FIG. 1) located on the printed circuit board 108 to the socket 112.

The backplate 104 is attached to the printed circuit board 108 via fasteners 132 (e.g., studs) that extend through holes 136 in the printed circuit board 108 and attach to counterpart fasteners 140 of the bolster plate 116. The socket 112 is attached to the printed circuit board 108 and the integrated circuit component 120 is attached to the socket 112. The thermal management solution loading mechanism comprises attachment of the thermal management solution 128 to the bolster plate 116 via fasteners 144 (e.g., studs) that are part of the bolster plate 116 that extend through the carrier 124 and attach to counterpart fasteners 148 in the thermal management solution 128. Although the socket 112 is an LGA socket, in other embodiments, the socket 112 can be any other type of socket to which an integrated circuit component can attach, such as a PGA (pin grid array) or BGA (ball grid array) socket.

A layer of thermal interface material (not shown in FIG. 1) is located between the thermal management solution 128 and the integrated circuit component 120 to assist in the conduction of heat generated by the integrated circuit component 120 to the thermal management solution 128. That is, the layer of thermal interface material thermally conductively couples the thermal management solution 128 to the integrated circuit component 120. The thermal management solution 128 comprises a primary heat sink 152 and secondary heat sinks 156. Heat pipes 160 attached at a first end to the primary heat sink 152 and at a second end to a secondary heat sink 156 provide for the transport of heat from the primary heat sink 152 to the secondary heat sinks 156.

The thermal management solution illustrated in FIG. 1 can be considered to have an “outrigger” configuration due to the shape of the heat pipes 160 and the location, size, and orientation of the secondary heat sinks 156 relative to the primary heat sink 152. In some embodiments, a thermal management solution comprising a primary heat sink, heat pipes, and secondary heat sinks and having the “outrigger” configuration illustrated in FIG. 1 can be an Intel® Extended Volume Air Cooling (EVAC) thermal management solution.

The technologies disclosed herein can be used in systems comprising thermal management solutions that have the outrigger configuration illustrated in FIG. 1, variations of the thermal management solution illustrated in FIG. 1, or any other suitable type of thermal management solution. Variations of the thermal management solution illustrated in FIG. 1 include the use of thermosiphons in place of heat pipes 160 and heat sinks with fins in place of the solid primary and second heat sinks 152 and 156 illustrated in FIG. 1. In other embodiments, the thermal management solution can comprise a cold plate or a vapor chamber, a thermal management solution in which a cold plate or vapor chamber is part of a closed-loop liquid cooling system (that can further comprise a heat exchanger, a pump, and one or more tubes connecting the heat exchanger to the cold plate or vapor chamber), or an immersion bath-based liquid cooling thermal management solution.

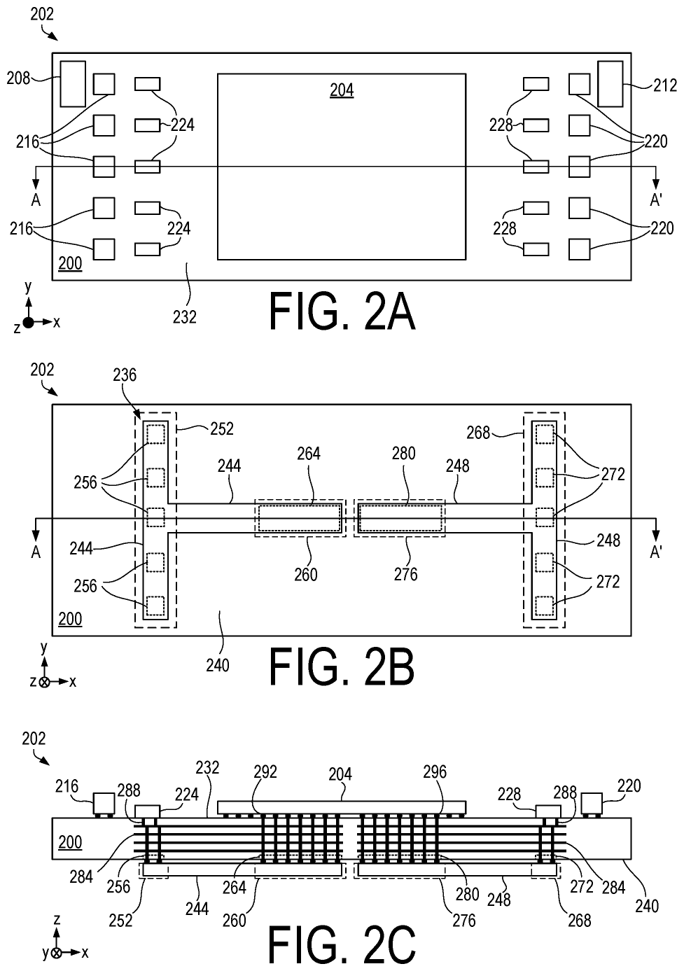

FIGS. 2A-2C illustrate top, bottom, and cross-sectional views, respectively of an example multi-entry socket power delivery structure attached to an example printed circuit board. FIG. 2A illustrates a top view of an apparatus 202 comprising a multi-entry socket power delivery structure 236 attached to a printed circuit board 200. A socket 204, voltage regulator controllers 208 and 212, voltage regulators 216 and 220, and inductors 224 and 228 are attached to a front surface 232 of the printed circuit board 200. A first power supply signal generation circuit comprising the voltage regulator controller 208, voltage regulators 216, and inductors 224 is located on a first side of the socket 204 and provides a first power supply signal to the socket 204. A second power supply signal generation circuit comprising the voltage regulator controller 212, voltage regulators 220, and inductors 228 is located on an opposite side of the socket 204 and provides a second power supply signal to the socket 204. In some embodiments, the first and second power supply signals provided to the socket 204 can be different power signals, such as a power signal supplied to digital “core” portions of the integrated circuit component (e.g., VDD), a power signal supplied to data signal transceivers (e.g., VDDQ), or another power signal (such as a power signal provided to memory components of the integrated circuit component (e.g., Vmem)). In other embodiments, the first and second power supply signal generation circuits can supply the same power supply signal to the socket 204.

FIG. 2B illustrates a bottom view of the apparatus 202. The multi-entry socket power delivery structure 236 is attached to a back surface 240 of the printed circuit board 200. The power delivery structure 236 comprises a first portion 244 and a second portion 248 that is physically separate from the first portion 244. The first portion 244 comprises a printed circuit board connection portion 252 where the first portion 244 attaches to the back surface 240 of the printed circuit board 200 at connection regions 256 of the printed circuit board 200 and a socket connection portion 260 where the first portion 244 attaches to the back surface 240 of the printed circuit board at a socket connection region 264. The second portion 248 comprises a printed circuit board connection portion 268 where the second portion 248 attaches to the back surface 240 at connection regions 272 of the printed circuit board 200 and a socket connection portion 276 where the second portion 248 attaches to the back surface 240 at a socket connection region 280 of the printed circuit board 200. The printed circuit board connection regions 256 and 272 comprise conductive contacts (e.g., bond pads) to which power signals generated by the voltage regulators 216 and 220, respectively, are routed through the printed circuit board 200 and made available for connection to the multi-entry socket power delivery structure 236. The socket connection regions 264 and 280 comprise conductive contacts to which power signals can be delivered from the power delivery structure 236 and delivered to power pins 292 and 296 of the socket 204.

FIG. 2C is a cross-sectional view of the apparatus 202 taken along line A-A′ of FIGS. 2A and 2B. The printed circuit board 200 comprises interconnect traces 284 belonging to multiple interconnect layers and vias 288 that interconnect the interconnect traces 284. The interconnect traces 284 and vias 288 provide paths for power signals generated by the voltage regulators attached to the surface 232 of the printed circuit board 200 to be delivered to power pins of the socket 204 (e.g., power pins 292, 296) and comprise to aforementioned printed circuit board “power corridor”. The interconnect traces that deliver power signals to the socket can be dedicated for power delivery and can be thicker than other interconnect layers in the printed circuit board. Still, the power corridor can provide a power delivery bottleneck. The multi-entry socket power delivery structure 236 provides an additional path for power signals to be delivered to the socket. The power delivery structure 236 can comprise copper, another metal, or other suitable conductive material and the thickness of the structure 236 can be thicker than any of the interconnect traces 284 of the power corridor. As such, the power delivery structure 236 may provide a lower-resistance path for a power supply signal being provided to the socket from the voltage regulators than that presented by the printed circuit board 200. The power delivery structure 236 may thus enable the delivery of a desired amount of power supply current to a socket that is attached to a printed circuit board that is thinner than a printed circuit board that would be required to deliver the desired amount of current if the power delivery structure 236 were not utilized. That is, the use of a multi-entry socket power delivery structure may enable the use of printed circuit boards in high-performance processor systems that have fewer and/or thinner metal layers than printed circuit boards in systems that do not utilize multi-entry socket power delivery structures.

The multi-entry socket power delivery structure 236 illustrated in FIGS. 2A-2C is a dual-entry structure in that it provides for the entry of power signals to the socket 204 via two separate paths—a first path comprising the first portion 244 and a second path comprising the second portion 248. In other embodiments, a multi-entry socket power delivery structure can comprise more than two portions and thus provide for the entry of power signals to a socket via more than two paths. Such multi-entry socket power delivery structures are discussed further below.

The printed circuit board 200, as well as any other printed circuit board described or referenced herein, comprises multiple electrically conductive interconnect layers separated from one another by layers of dielectric material (e.g., FR-4 or other fiberglass-reinforced epoxy laminate) and electrically conductive vias. The individual interconnect layers comprise a plurality of interconnect traces and the electrically conductive vias connect an interconnect trace on a first interconnect layer to an interconnect trace on a second interconnect layer or to a conductive contact (e.g., bond pad) on a surface of the printed circuit board. The interconnect layers in a printed circuit board can comprise copper, aluminum, or another suitable conductive material. The vias in a printed circuit board can comprise copper or another suitable conductive material.

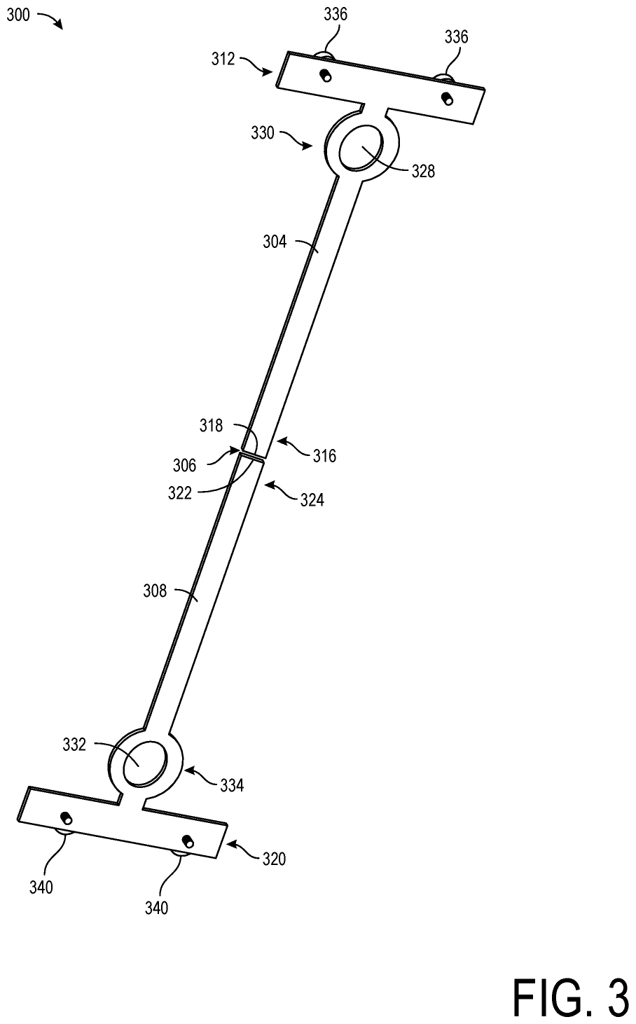

FIG. 3 is a perspective view of an example dual-entry socket power delivery structure. The structure 300 comprises a first portion 304 and a second portion 308. The two portions are generally T-shaped and physically separate from each other, as indicated by the gap 306 between the first portion 304 and the second portion 308. The first portion 304 comprises a printed circuit board connection portion 312 at which the first portion 304 is attachable to a printed circuit board to receive power signals to be delivered to a socket, and a socket connection portion 316 at which the first portion 304 is to attach to a printed circuit board to provide power signals for delivery to a socket. The second portion 308 comprises a printed circuit board connection portion 320 at which the second portion 308 is to attach to a printed circuit board to receive power signals to be delivered to a socket, and a socket connection portion 324 at which the second portion 308 is to attach to a printed circuit board to provide power signals for delivery to a socket.

The first portion 304 comprises holes 328 and rings 330 and the second portion 308 comprises holes 332 and rings 334 that accommodate electrical components (e.g., a capacitor) attached to the surface of the printed circuit board to which the structure 300 is to attach. The first portion 304 and the second portion 308 further comprise fasteners 336 and 340 (e.g., screws), respectively, to secure the structure 300 to a printed circuit board. Fasteners 336 and 340 comprise two screws, but in other embodiments, more or fewer fasteners can be used for securing a portion of a power delivery structure to a printed circuit board. In some embodiments, a portion of a multi-entry socket power delivery structure can comprise no fasteners, and the portion is secured to a printed circuit board by attachment (e.g., via soldering) of the structure to the conductive contacts of the printed circuit board that provide power signals generated by voltage regulators and deliver power signals to socket power pins. In other embodiments, fasteners other than screws can be used.

The structure 300 illustrated in FIG. 3 is one of many possible shapes that a multi-entry socket power delivery structure may take. The shape of a portion of a multi-entry socket power delivery structure can vary depending on the location and configuration of socket power pins on the printed circuit board that the portion is to attach to, the location and configuration of conductive contacts that provide power signals generated by voltage regulators that the portion is to attach to, and/or the location and configuration of electrical components attached to the surface of the printed circuit board to which the power delivery structure is to attach and that the portion is to accommodate. That is, in some embodiments, a portion of a power delivery structure can have a shape different from the T-shaped portions illustrated in FIGS. 2B, 3, 4A, and 5, including shapes that have more holes than shown in FIG. 3 or no holes at all. In other embodiments, the multi-entry power delivery structure comprises more than two portions. Such embodiments can be used to provide entry of more than two power signals to the power pins of a socket. In some embodiments, any portion of a multi-entry socket power delivery structure can have a different length, width, and/or thickness than that illustrated in FIG. 3. For example, power delivery structure portions that carry larger amounts of current can be thicker and/or wider than portions that carry lesser amounts of current in other embodiments.

As the multi-entry power delivery structure 300 is generally bar-shaped (in that it comprises two closely-spaced elongated T-shaped portions placed end-to-end) and functions as a power bus, the structure 300 can be referred to as a “bus bar”. Multi-entry power delivery structures and dual-entry power delivery structures can thus be referred to as multi-entry bus bars and dual-entry bus bars, respectively.

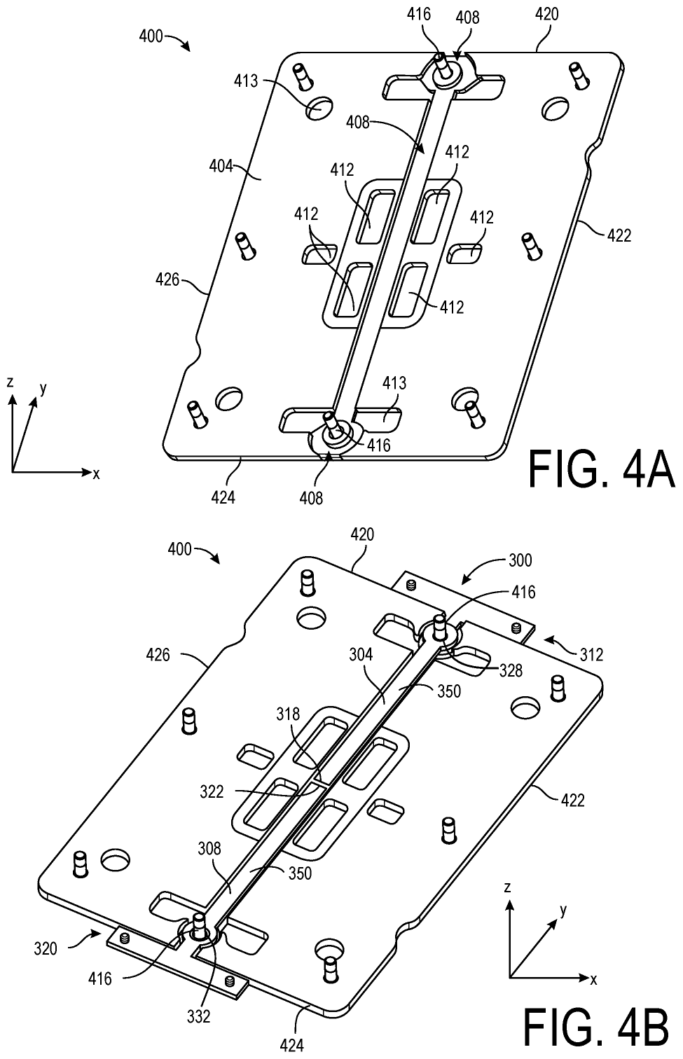

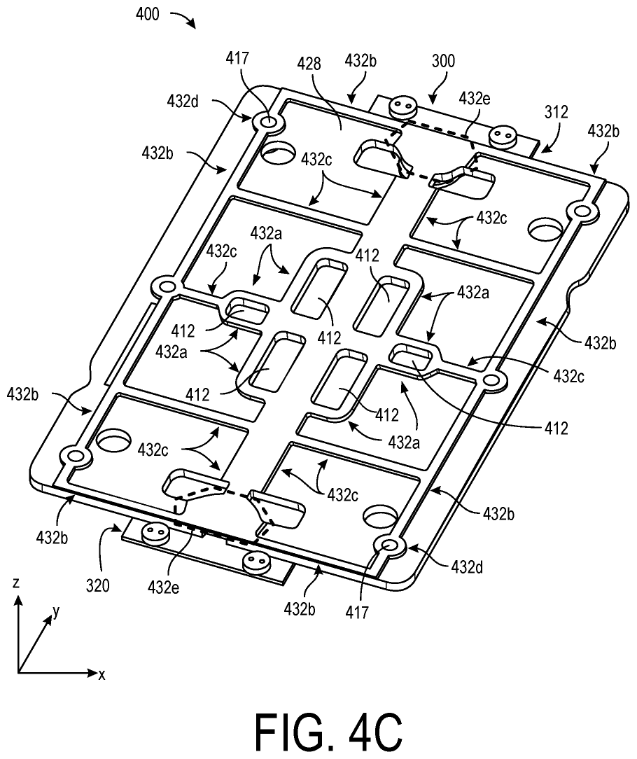

FIG. 4A is a front perspective view of an example backplate. The backplate 400 comprises a substantially planar front surface 404, a recess or groove 408 formed in the front surface 404, cavities 412 and 413, and fasteners 416 that extend upwards from the front surface 404. The recess 408 accommodates a multi-entry socket power delivery structure (e.g., structure 300) and extends from a first edge 420 of the backplate 400 to a second edge 424 of the backplate 400 that is opposite to the first edge 420. The cavities 412 and 413 accommodate electrical components attached to the printed circuit board surface to which the backplate 400 is to attach and thus allow surface 404 of the backplate 400 to be positioned against the printed circuit board surface when the backplate is attached to the printed circuit board. The fasteners 416 (illustrated as studs in FIG. 4A) extend through holes in a printed circuit board to attach to a corresponding fastener (such as a fastener located on a bolster plate (see FIG. 1)) to secure the backplate 400 to the printed circuit board. The configuration of cavities in the backplate 400 is just one possible configuration. A myriad of other configurations are possible, with the cavity configuration of a particular backplate design accommodating electrical components attached to the surface of a printed circuit board to which the backplate is to be attached. In addition, in other embodiments, the backplate can comprise more or fewer than the eight fasteners 416 shown in FIG. 4A. In some embodiments, the recess 408 is between 1.0 and 1.5 millimeters in depth. In other embodiments, the recess 408 has a depth of 1.2 millimeters.

FIG. 4B is a front perspective view of the example multi-entry socket power delivery structure of FIG. 3 positioned on the surface of the example backplate of FIG. 4A. Top surfaces 350 of the power delivery structure 300 can be substantially flush with the surface 404 of the backplate 400. The printed circuit board connection portion 312 of the first portion 304 of the structure 300 is positioned at the first edge 420 of the backplate 400 and the printed circuit board connection portion 320 of the second portion 308 of the structure 300 is positioned at the second edge 424 of the backplate 400. Two of the fasteners 416 extend through the holes 328 and 332 of the power delivery structure 300. Although the printed circuit board connection portions 312 and 320 are illustrated as physically abutting the edges 420 and 424 of the backplate 400, in other embodiments, there can be space between a printed circuit board connection portions and a backplate edge. In some embodiments where the backplate comprises a metal, the backplate can further comprise a non-electrically conductive coating that covers at least the portions of the backplate where the power delivery structure 300 contacts the backplate.

FIG. 4C illustrates a back perspective view of the example multi-entry socket power delivery structure of FIG. 3 located on the example backplate of FIG. 4A. A back surface 428 of the backplate comprises reinforcement features 432a-432e in the form of regions that have a raised surface relative to the portions of the backplate that do not comprise reinforcement features. As the front surface 404 of the backplate 400 is substantially planar, the regions of the backplate 400 having a raised surface have an increased thickness relative to other portions of the backplate and can thus function as structural reinforcements for the backplate 400. In some embodiments, the regions of the backplate 400 without reinforcement features can have a thickness in the range of 2.5 to 3.0 millimeters. In some embodiments, the regions of the backplate 400 without reinforcement features have a thickness of about 2.8 millimeters.

The reinforcement features 432 comprise reinforcement features 432a that fully or partially surround cavities 412, reinforcement features 432b and 432c that function as “ribs” to mitigate backplate deflections, reinforcement features 432d that provide reinforcement around base portions 417 of fasteners 416, and reinforcement features 432e that provide reinforcement at the printed circuit board connection portions of the multi-entry socket power delivery structure 300. In embodiments where the socket is a land grid array (LGA) socket, the reinforcement features 432a can improve contact between the socket pins and the pads on the integrated circuit component package. Reinforcement features 432b and 432c extend along at least a portion of the length or width of the backplate. The reinforcement features 432b provide mechanical reinforcement along the edges of the backplate 400 and reinforcement features 432c provide mechanical reinforcement across interior regions of the backplate 400. As can be seen in FIG. 4B, some of the reinforcement features 432b extend from a first fastener to a second fastener. Reinforcement features 432e comprise the polygonal reinforcement regions (surrounded by dashed lines in FIG. 4C) near the printed circuit board connection portions 312 and 320. The reinforcement features 432e can be any shape in other embodiments. The reinforcement features 432c that extend between the reinforcement features 432e are wider than the other reinforcement features 432b or 432c.

In some embodiments, a backplate 400 may comprise more or fewer reinforcement features than shown in FIG. 4C. For example, in some embodiments, reinforcement features 432a surround cavities in addition to those located at a socket connection region or reinforcement features 432a could surround fewer cavities in a socket connection region than shown in FIG. 4C. In other embodiments, a backplate comprises only reinforcement rib features that are located along the edges of the backplate, only reinforcement rib features that are located in the interior region of the backplate, have more or fewer interior region reinforcement rib features than shown in FIG. 4C, or have reinforcement rib features that are wider or narrower than those shown in FIG. 4C. A backplate can comprise reinforcement features based on loading points for a specific processor stack and thermal management solution loading mechanism solution. For example, in embodiments where the loading points on the backplate are along the long edges of the backplate, the backplate can comprise reinforcement rib features along the long edges of the backplate. In another example, in embodiments where the backplate loading points are at the four corners of a backplate, the reinforcement features can comprise reinforcement rib features backplate that extend to the four corners of the backplate.

In some embodiments, the reinforcement features can comprise a reinforcement structure that is a physically separate component from the backplate and is insertable into recesses in a front surface of the backplate. In some embodiments, the reinforcement structure can comprise a material that is stiffer than the backplate material. For example, if the backplate comprises copper, the reinforcement structure can comprise steel, aluminum, an aluminum alloy, or a nickel alloy. In another example, if the reinforcement structure comprises steel, the backplate can comprise copper or aluminum. In some embodiments, the reinforcement structure can comprise the same material as the backplane but have a thickness such that when the reinforcement structure is inserted into the recesses on the front surface of the backplate, the thickness of the backplate plus the thickness of the reinforcement structure is greater than the thickness of backplate in regions of the backplate where there is not a recess on the front backplate surface.

In some embodiments, a backplate does not comprise raised regions on a back surface or a reinforcement structure located in recesses on the back surface (that is, the back surface of the backplate is substantially planar), and the backplate is reinforced by way of having a thickness sufficient to provide a desired amount of structural integrity. In some embodiments, backplate reinforcements can counter the reduction in the structural integrity of the backplate resulting from the creation of recesses or grooves in the backplate made to accommodate a multi-entry socket power delivery structure.

The multi-entry socket power delivery structure 300 illustrated in FIGS. 3 and 4A-4C illustrate just one possible power delivery structure design. In some embodiments, a dual-entry socket power delivery structure can comprise two portions that deliver current to socket power pins from printed circuit board connection portions that are positioned at adjacent edges of a backplate. For example, with reference to FIG. 4B, such dual-entry power delivery structures could comprise the portion 304 with a second portion that comprises a printed circuit board connection portion that is positioned adjacent to an edge 422 of the backplate, the edge 422 being adjacent to edge 420 of the backplate.

In some embodiments, the multi-entry socket power delivery structure can comprise three portions that provide three different power supply signals to a socket from three different printed circuit board connection portions positioned at three different edges of the backplate. For example, with reference to FIG. 4B, a tri-entry socket power delivery structure can be similar to structure 300, but with an additional third portion that has a printed circuit board connection portion positioned adjacent to an edge 422 of the backplate 400, the edge 422 being adjacent to edges 420 and 424.

Further, in some embodiments, the multi-entry socket power delivery structure can comprise four portions that provide four different power supply signals to a socket from four different printed circuit board connection portions positioned at four different edges of the backplate. For example, with reference to FIG. 4B, a quad-entry socket power delivery structure can be similar to structure 300, but with additional third and fourth portions that have printed circuit board connection portions positioned adjacent to edges 422 and 426 of the backplate 400, respectively, the edge 426 being adjacent to edges 420 and 424 of the backplate 400.

In other embodiments, a multi-entry socket power delivery structure can comprise two or more portions with printed circuit board connection portions positioned adjacent to the same side of the backplate. In any multi-entry socket power delivery structure, a portion can deliver a power signal belonging to the same or a different voltage domain (e.g., VDD, VDDQ, Vmem) as another portion of the power delivery structure.

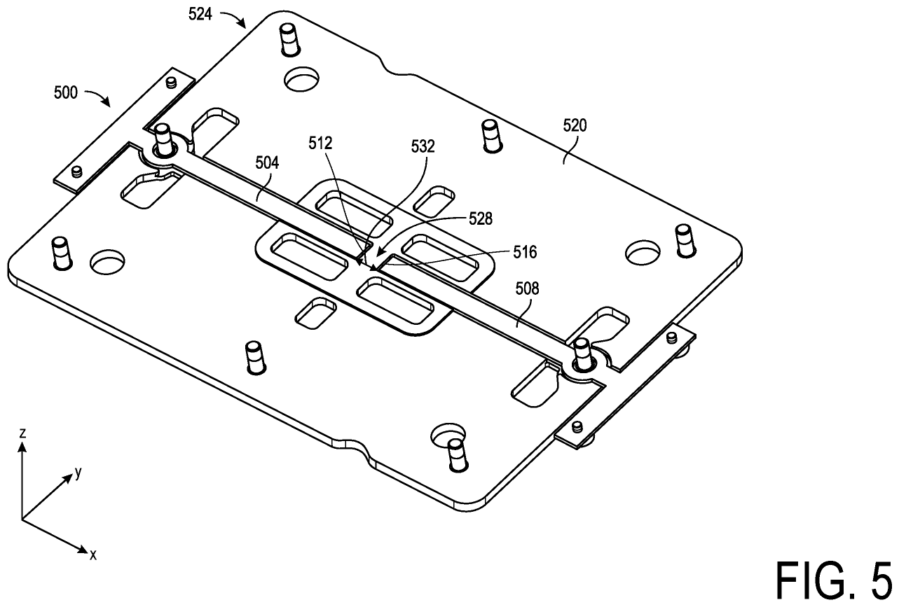

FIG. 5 is a front perspective view of a multi-entry socket power delivery structure located on a backplate comprising a bridge between portions of the multi-entry socket power delivery structure. The multi-entry socket power delivery structure 500 comprises a first portion 504 and a second portion 508. The first portion 504 and the second portion 508 have a first end 512 and a second end 516, respectively, and the first portion 504 and the second portion 508 reside in recesses in the front surface 520 of the backplate 524. The backplate 524 comprises a bridge 528 between the first end 512 and the second end 516. This is in contrast to the multi-entry socket power delivery structure and backplate embodiment illustrated in FIGS. 3 and 4A-4C in which ends 318 and 322 of the first and second portions 304 and 308, respectively, reside in a continuous recess in the front surface 404 of the backplate 400 and there is no bridge between the ends 318 and 322. The presence of the bridge 528 can increase the structural integrity of the backplate 524. In some embodiments, the width 532 of the bridge is at least about five millimeters.

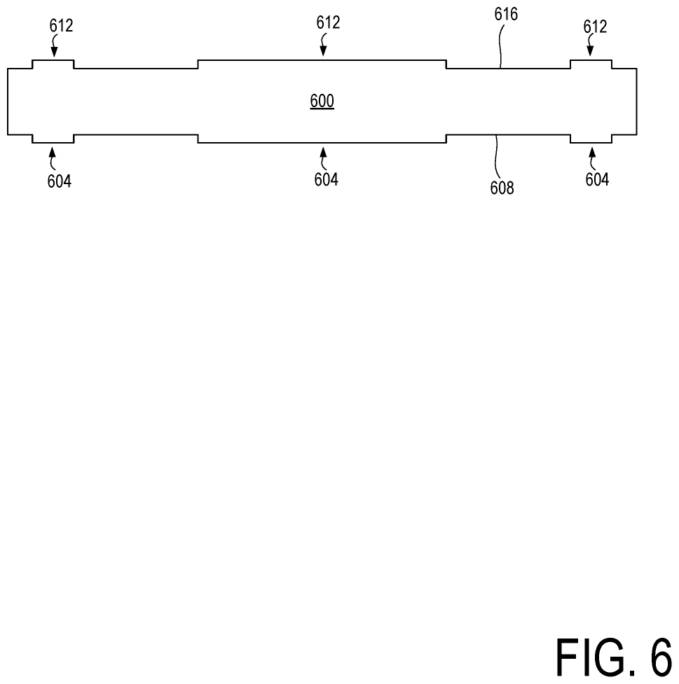

FIG. 6 is a cross-sectional view of an example backplate with reinforcement features located on front and back surfaces of the backplate. The backplate 600 comprises reinforcement features 604 on a back surface 608 of the backplate 600 (the surface of the backplate 600 facing away from the printed circuit board when the backplate 600 is attached to the printed circuit board) and reinforcement features 612 and a front surface 616 of the backplate 600 (the surface of the backplate 600 facing towards the printed circuit board when the backplate 600 is attached to the printed circuit board). The reinforcement features 604 and 612 are in the form of thicker regions of the backplate. In other embodiments, reinforcement features on a front side of a backplate can comprise a reinforcement structure located in one or more recesses on the front side of a backplate, such as the reinforcement structure discussed above with reference to FIG. 4C.

The multi-entry socket power delivery structures and backplates can be made by stamping, forging, metal injection molding, any combination of these processes, or any other suitable manufacturing process. Any of the multi-entry power delivery structures (or bus bar) disclosed herein can comprise copper, steel, aluminum, an aluminum alloy, a nickel alloy, or other suitable conductive material. Any of the backplates disclosed herein can comprise copper, steel, aluminum, an aluminum alloy, a nickel alloy, or other suitable conductive material.

The multi-entry socket power delivery structures and backplates described herein can be included in any computing system or computing device comprising an integrated circuit component mounted on a printed circuit board. In some embodiments, one or more additional integrated circuit components or other components (e.g., battery, antenna) can be attached to the printed circuit board. In some embodiments, the printed circuit board can be located in a computing device comprising a housing that encloses the printed circuit board.

The multi-entry socket power delivery structures and backplate technologies described herein can included in a variety of computing systems, including desktop computers, servers, workstations, stationary gaming consoles, and rack-level computing solutions (e.g., blade, tray, or sled computing systems)). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

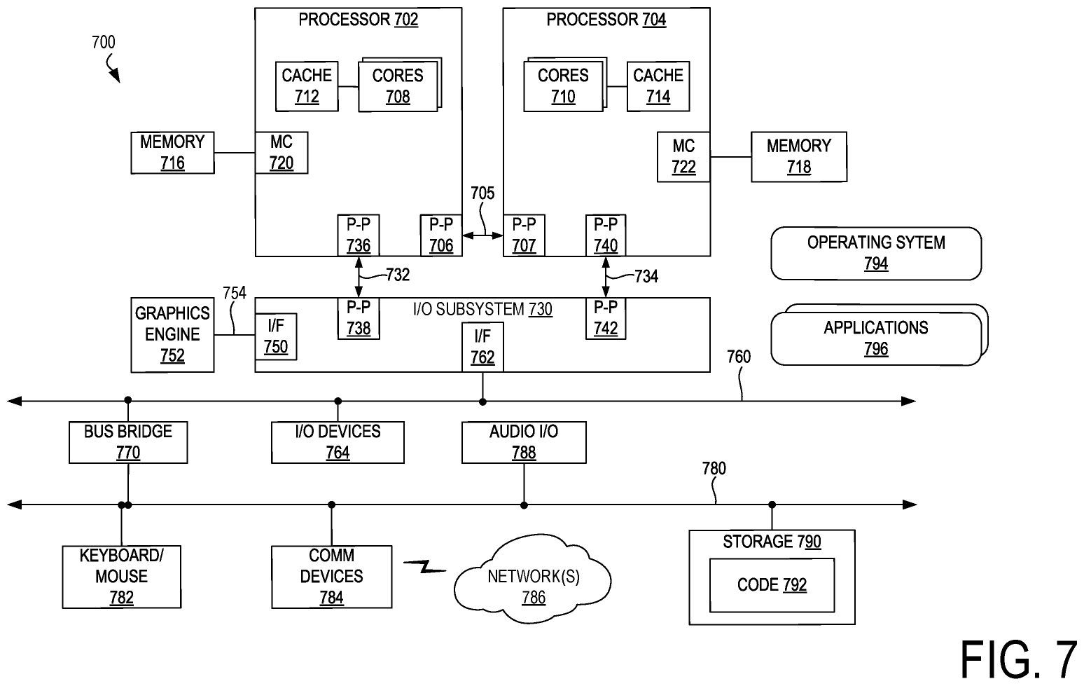

FIG. 7 is a block diagram of an example computing system in which the multi-entry socket power delivery structures and backplates described herein may be implemented. Generally, components shown in FIG. 7 can communicate with other shown components, although not all connections are shown, for case of illustration. The computing system 700 is a multiprocessor system comprising a first processor unit 702 and a second processor unit 704 comprising point-to-point (P-P) interconnects. A point-to-point (P-P) interface 706 of the processor unit 702 is coupled to a point-to-point interface 707 of the processor unit 704 via a point-to-point interconnection 705. It is to be understood that any or all of the point-to-point interconnects illustrated in FIG. 7 can be alternatively implemented as a multi-drop bus, and that any or all buses illustrated in FIG. 7 could be replaced by point-to-point interconnects.

The processor units 702 and 704 comprise multiple processor cores. Processor unit 702 comprises processor cores 708 and processor unit 704 comprises processor cores 710.

Processor units 702 and 704 further comprise cache memories 712 and 714, respectively. The cache memories 712 and 714 can store data (e.g., instructions) utilized by one or more components of the processor units 702 and 704, such as the processor cores 708 and 710. The cache memories 712 and 714 can be part of a memory hierarchy for the computing system 700. For example, the cache memories 712 can locally store data that is also stored in a memory 716 to allow for faster access to the data by the processor unit 702. In some embodiments, the cache memories 712 and 714 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 700 is shown with two processor units, the computing system 700 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 700 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 702 and 704 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 702 and 704 further comprise memory controller logic (MC) 720 and 722. As shown in FIG. 7, MCs 720 and 722 control memories 716 and 718 coupled to the processor units 702 and 704, respectively. The memories 716 and 718 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 720 and 722 are illustrated as being integrated into the processor units 702 and 704, in alternative embodiments, the MCs can be external to a processor unit.

Processor units 702 and 704 are coupled to an Input/Output (I/O) subsystem 730 via point-to-point interconnections 732 and 734. The point-to-point interconnection 732 connects a point-to-point interface 736 of the processor unit 702 with a point-to-point interface 738 of the I/O subsystem 730, and the point-to-point interconnection 734 connects a point-to-point interface 740 of the processor unit 704 with a point-to-point interface 742 of the I/O subsystem 730. Input/Output subsystem 730 further includes an interface 750 to couple the I/O subsystem 730 to a graphics engine 752. The I/O subsystem 730 and the graphics engine 752 are coupled via a bus 754.

The Input/Output subsystem 730 is further coupled to a first bus 760 via an interface 762. The first bus 760 can be a Peripheral Component Interconnect Express (PCIe) bus or any other type of bus. Various I/O devices 764 can be coupled to the first bus 760. A bus bridge 770 can couple the first bus 760 to a second bus 780. In some embodiments, the second bus 780 can be a low pin count (LPC) bus. Various devices can be coupled to the second bus 780 including, for example, a keyboard/mouse 782, audio I/O devices 788, and a storage device 790, such as a hard disk drive, solid-state drive, or another storage device for storing computer-executable instructions (code) 792 or data. Additional components that can be coupled to the second bus 780 include communication device(s) 784, which can provide for communication between the computing system 700 and one or more wired or wireless networks 786 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 702.11 standard and its supplements).

The system 700 can comprise removable memory such as flash memory cards. The memory in system 700 (including caches 712 and 714, memories 716 and 718, and storage device 790) can store data and/or computer-executable instructions for executing an operating system 794 and application programs 796. The system 700 can also have access to external memory or storage (not shown) such as external hard drives or cloud-based storage.

The computing system 700 can support various additional input devices, such as a touchscreen, microphone, and camera, and one or more output devices, such as one or more displays. Any of the input or output devices can be internal to, external to, or removably attachable with the system 700. External input and output devices can communicate with the system 700 via wired or wireless connections.

The system 700 can further include at least one input/output port comprising physical connectors (e.g., USB, IEEE 1394 (Fire Wire), Ethernet, RS-232), and/or a power supply (e.g., battery), a global satellite navigation system (GNSS) receiver (e.g., GPS receiver); a gyroscope;

an accelerometer; and/or a compass. A GNSS receiver can be coupled to a GNSS antenna. The computing system 700 can further comprise one or more additional antennas coupled to one or more additional receivers, transmitters, and/or transceivers to enable additional functions.

It is to be understood that FIG. 7 illustrates only one example computing system architecture. Computing systems based on alternative architectures can be used to implement technologies described herein. For example, instead of the processors 702 and 704 and the graphics engine 752 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 7. Moreover, the illustrated components in FIG. 7 are not required or all-inclusive, as shown components can be removed and other components added in alternative embodiments.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising: a backplate comprising a surface, the surface comprising one or more recesses; and a structure comprising a metal, the structure located in the one or more recesses, the structure comprising a plurality of portions, a first portion of the plurality of portions comprising a first printed circuit board connection portion positioned at a first edge of the backplate, a second portion of the plurality of portions comprising a second printed circuit board connection portion positioned at a second edge of the backplate.

Example 2 comprises the apparatus of Example 1, wherein the backplate further comprises a plurality of fasteners.

Example 3 comprises the apparatus of Example 1 or 2, wherein the backplate further comprises one or more reinforcement features.

Example 4 comprises the apparatus of Example 3, wherein the one or more reinforcement features comprises a first region of the backplate that has a thickness that is greater than a thickness of a second region of the backplate that does not comprise a reinforcement feature.

Example 5 comprises the apparatus of Example 4, wherein the thickness of the second region is in a range of 2.5 to 3.0 millimeters.

Example 6 comprises the apparatus of Example 4, wherein the thickness of the second region is about 2.8 millimeters.

Example 7 comprises the apparatus of Example 3, wherein the surface is a first surface and the one or more recesses are one or more first recesses, the apparatus further comprising: a second surface that is opposite to the first surface; and one or more second recesses located on the second surface, the one or more reinforcement features comprising a reinforcement structure located in the one or more second recesses, the reinforcement structure a physically separate component from the backplate.

Example 8 comprises the apparatus of Example 7, wherein the reinforcement structure comprises a first metal and the backplate comprises a second metal, the first metal different from the second metal.

Example 9 comprises the apparatus of Example 7, wherein the reinforcement structure comprises a metal.

Example 10 comprises the apparatus of any one of Examples 1-9, wherein the first portion is physically separate from the second portion.

Example 11 comprises the apparatus of Example 3, wherein the backplate comprises a cavity and the one or more reinforcement features comprise a reinforcement feature that at least partially surrounds the cavity.

Example 12 comprises the apparatus of Example 3, wherein the backplate comprises a fastener and the one or more reinforcement features comprises a reinforcement feature that surrounds a base portion of the fastener.

Example 13 comprises the apparatus of Example 3, wherein the one or more reinforcement features comprises a reinforcement feature that extends along at least a portion of a length or a width of the backplate.

Example 14 comprises the apparatus of Example 3, wherein the backplate comprises four edges and the one or more reinforcement features comprises four reinforcement features, individual of the four reinforcement features extending along at least of a portion of a length of one of the four edges of the backplate.

Example 15 comprises the apparatus of Example 3, wherein the backplate comprises a first fastener and a second fastener, the one or more reinforcement features comprising a reinforcement feature that extends from the first fastener to the second fastener.

Example 16 comprises the apparatus of Example 1, wherein the first portion is physically separate from the second portion, an end of the first portion is located in a first recess of the one or more recesses, and an end of the second portion is located in a second recess of the one or more recesses, the first recess physically spaced from the second recess.

Example 17 comprises the apparatus of Example 16, wherein the first recess is physically spaced from the second recess by at least about five millimeters.

Example 18 comprises the apparatus of Example 1, wherein the first portion is physically separate from the second portion, an end of the first portion is located in a first recess of the one or more recesses, and an end of the second portion is located in a second recess of the one or more recesses, a bridge of the backplate separating the first recess from the second recess.

Example 19 comprises the apparatus of any one of Examples 1-18, wherein the first edge of the backplate is opposite to the second edge of the backplate.

Example 20 comprises the apparatus of any one of Examples 1-18, wherein the first edge of the backplate is adjacent to the second edge of the backplate.

Example 21 comprises the apparatus of any one of Examples 1-18, wherein a third portion of the plurality of portions comprises a third printed circuit board connection portion positioned at a third edge of the backplate.

Example 22 comprises the apparatus of Example 21, wherein a fourth portion of the plurality of portions comprises a fourth printed circuit portion positioned at a fourth edge of the backplate.

Example 23 comprises the apparatus of Example 3, wherein a third portion of the plurality of portions comprises a third printed circuit board connection portion positioned at the first edge of the backplate.

Example 24 comprises the apparatus of Example 3, wherein the surface is a first surface and the one or more reinforcement features are one or more first reinforcement features, the apparatus further comprising one or more second reinforcement features located on a second surface of the backplate, the second surface opposite to the first surface of the backplate.

Example 25 is a system, comprising: a backplate comprising a backplate surface, the backplate surface comprising one or more recesses; a structure comprising a metal, the structure located in the one or more recesses, the structure comprising a plurality of portions comprising a first portion and a second portion, the first portion of the plurality of portions comprising: a first socket connection portion; and a first printed circuit board connection portion positioned at a first edge of the backplate; the second portion of the plurality of portions comprising: a second socket connection portion; and a second portion of the plurality of portions comprising a second printed circuit board connection portion positioned at a second edge of the backplate; and a printed circuit board, the structure attached to the printed circuit board at the first printed circuit board connection portion, the second printed circuit board connection portion, the first socket connection portion, and the second socket connection portion of the structure.

Example 26 comprises the system of Example 25, wherein the printed circuit board comprises a first surface and a second surface opposite to the first surface, the structure attached to the first surface of the printed circuit board, the system further comprising a socket attached to the second surface of printed circuit board at a plurality of conductive contacts, at least one of the plurality of conductive contacts electrically conductively coupled to the structure via one or more interconnect traces and one or more vias in the printed circuit board.

Example 27 comprises the system of Example 26, wherein the one or more interconnect traces are one or more first interconnect traces and the one or more vias are one or more first vias, the system further comprising a voltage regulator attached to the second surface of the printed circuit board, the voltage regulator electrically conductively coupled to the structure by one or more second interconnect traces and one or more second vias in the printed circuit board.

Example 28 comprises the system of any one of Examples 25-27, further comprising a bolster plate, the backplate attached to printed circuit board via attachment of the bolster plate to the backplate.

Example 29 comprises the system of any one of Examples 25-27, further comprising: a socket attached to the printed circuit board; and an integrated circuit component attached to the socket.

Example 30 comprises the system of Example 29, further comprising a thermal management solution thermally conductively coupled to the integrated circuit component via a layer of thermal interface material positioned between the thermal management solution and the integrated circuit component.

Example 31 comprises the system of Example 30, wherein the thermal management solution comprises a heat sink.

Example 32 comprises the system of Example 25, wherein the backplate further comprises one or more reinforcement features.

Example 33 comprises the system of Example 32, wherein the one or more reinforcement features comprise a first region of the backplate that has a thickness that is greater than a thickness of a second region of the backplate that does not comprise a reinforcement feature.

Example 34 comprises the system of Example 33, wherein the backplate surface is a first backplate surface and the one or more recesses are one or more first recesses, the system further comprising: a second backplate surface that is opposite to the first backplate surface; and one or more second recesses located on the second backplate surface, the one or more reinforcement features comprising a reinforcement structure located in the one or more second recesses, the reinforcement structure a physically separate component from the backplate.

Example 35 comprises the system of Example 34, wherein the reinforcement structure comprises a first metal and the backplate comprises a second metal, the first metal different from the second metal.

Example 36 comprises the system of Example 34, wherein the reinforcement structure comprises a metal.

Example 37 comprises the system of Example 32, wherein the first portion is physically separate from second portion.

Example 38 comprises the system of Example 32, wherein the backplate comprises a cavity and the one or more reinforcement features comprise a reinforcement feature that at least partially surrounds the cavity.

Example 39 comprises the system of Example 32, wherein the backplate comprises a fastener and the one or more reinforcement features comprises a reinforcement feature that surrounds a base portion of the fastener.

Example 40 comprises the system of Example 32, wherein the one or more reinforcement features comprises a reinforcement feature that extends along at least a portion of a length or a width of the backplate.

Example 41 comprises the system of Example 32, wherein the backplate comprises four edges, and the one or more reinforcement features comprises four reinforcement features, individual of the four reinforcement features extending along at least of a portion of a length of one of the four edges of the backplate.

Example 42 comprises the system of Example 32, wherein the backplate comprises a first fastener and a second fastener, the one or more reinforcement features comprising a reinforcement feature that extends from the first fastener to the second fastener.

Example 43 comprises the system of Example 32, wherein the plurality of portions comprises a first portion and a second portion that is physically separate from the first portion, the first portion comprising the first printed circuit board connection portion, the second portion comprising the second printed circuit board connection portion.

Example 44 comprises the system of Example 25, wherein the first portion is physically separate from the second portion, an end of the first portion is located in a first recess of the one or more recesses, and an end of the second portion is located in a second recess of the one or more recesses, the first recess physically spaced from the second recess.

Example 45 comprises the system of Example 44, wherein the first recess is physically spaced from the second recess by at least about five millimeters.

Example 46 comprises the system of Example 25, wherein the first portion is physically separate from the second portion, an end of the first portion is located in a first recess of the one or more recesses, and an end of the second portion is located in a second recess of the one or more recesses, a bridge of the backplate separating the first recess from the second recess.

Example 47 comprises the system of any one of Examples 25-46, wherein the first edge of the backplate is opposite to the second edge of the backplate.

Example 48 comprises the system of any one of Examples 25-46, wherein the first edge of the backplate is adjacent to the second edge of the backplate.

Example 49 comprises the system of any one of Examples 25-46, wherein a third portion of the plurality of portions comprises a third printed circuit board connection portion positioned at a third edge of the backplate.

Example 50 comprises the system of Example 33, wherein a fourth portion of the plurality of portions comprises a fourth printed circuit portion positioned at a fourth edge of the backplate.

Example 51 comprises the system of Example 33, wherein a third portion of the plurality of portions comprises a third printed circuit board connection portion positioned at the first edge of the backplate.

Example 52 is an apparatus comprising: a printed circuit board; a socket attached to the printed circuit board; an integrated circuit component attached to the socket; a voltage regulator attached to the printed circuit board; a power supply delivery means for providing a power supply signal from the voltage regulator to the integrated circuit component; and a reinforcement means for providing structural integrity to the apparatus, the reinforcement means attached to the printed circuit board.

Example 53 comprises the apparatus of Example 52, wherein the printed circuit board comprises a first surface and a second surface opposite to the first surface, the power supply delivery means attached to the first surface of the printed circuit board, the apparatus further comprising a socket attached to the second surface of printed circuit board at a plurality of conductive contacts, at least one of the plurality of conductive contacts electrically conductively coupled to the power supply delivery means via one or more interconnect traces and one or more vias in the printed circuit board.

Example 54 comprises the apparatus of Example 53, wherein the one or more interconnect traces are one or more first interconnect traces and the one or more vias are one or more first vias, the apparatus further comprising a voltage regulator attached to the second surface of the printed circuit board, the voltage regulator electrically conductively coupled to the power supply delivery means by one or more second interconnect traces and one or more second vias in the printed circuit board.

Example 55 comprises the apparatus of any one of Examples 52-54, further comprising a bolster plate, the reinforcement means attached to printed circuit board via attachment of the bolster plate to the reinforcement means.

Example 56 comprises the apparatus of any one of Examples 52-55, further comprising: a socket attached to the printed circuit board; and an integrated circuit component attached to the socket.

Example 57 comprises the apparatus of any one of Examples 52-56, further comprising a thermal management solution thermally conductively coupled to the integrated circuit component via a layer of thermal interface material positioned between the thermal management solution and the integrated circuit component.

Example 58 comprises the apparatus of Example 57, wherein the thermal management solution comprises a heat sink.

1. An apparatus, comprising:
a backplate comprising a surface, the surface comprising one or more recesses; and
a structure comprising a metal, the structure located in the one or more recesses, the structure comprising a plurality of portions, a first portion of the plurality of portions comprising a first printed circuit board connection portion positioned at a first edge of the backplate, a second portion of the plurality of portions comprising a second printed circuit board connection portion positioned at a second edge of the backplate.

2. The apparatus of claim 1, wherein the backplate further comprises one or more reinforcement features.

3. The apparatus of claim 2, wherein the one or more reinforcement features comprises a first region of the backplate that has a thickness that is greater than a thickness of a second region of the backplate that does not comprise a reinforcement feature.

4. The apparatus of claim 2, wherein the surface is a first surface and the one or more recesses are one or more first recesses, the apparatus further comprising:
a second surface that is opposite to the first surface; and
one or more second recesses located on the second surface, the one or more reinforcement features comprising a reinforcement structure located in the one or more second recesses, the reinforcement structure a physically separate component from the backplate.

5. The apparatus of claim 2, wherein the backplate comprises a cavity and the one or more reinforcement features comprise a reinforcement feature that at least partially surrounds the cavity.

6. The apparatus of claim 2, wherein the backplate comprises a fastener and the one or more reinforcement features comprises a reinforcement feature that surrounds a base portion of the fastener.

7. The apparatus of claim 1, wherein the first portion is physically separate from the second portion, an end of the first portion is located in a first recess of the one or more recesses, and an end of the second portion is located in a second recess of the one or more recesses, the first recess physically spaced from the second recess.

8. The apparatus of claim 1, wherein the first edge of the backplate is opposite to the second edge of the backplate.

9. The apparatus of claim 1, wherein a third portion of the plurality of portions comprises a third printed circuit board connection portion positioned at a third edge of the backplate.

10. The apparatus of claim 1, wherein a third portion of the plurality of portions comprises a third printed circuit board connection portion positioned at the first edge of the backplate.

11. The apparatus of claim 10, wherein a fourth portion of the plurality of portions comprises a fourth printed circuit portion positioned at a fourth edge of the backplate.

12. The apparatus of claim 2, wherein the surface is a first surface and the one or more reinforcement features are one or more first reinforcement features, the apparatus further comprising one or more second reinforcement features located on a second surface of the backplate, the second surface opposite to the first surface of the backplate.

13. A system, comprising:
a backplate comprising a backplate surface, the backplate surface comprising one or more recesses;
a structure comprising a metal, the structure located in the one or more recesses, the structure comprising a plurality of portions comprising a first portion and a second portion, the first portion of the plurality of portions comprising:
a first socket connection portion; and
a first printed circuit board connection portion positioned at a first edge of the backplate;
the second portion of the plurality of portions comprising:
a second socket connection portion; and
a second portion of the plurality of portions comprising a second printed circuit board connection portion positioned at a second edge of the backplate; and
a printed circuit board, the structure attached to the printed circuit board at the first printed circuit board connection portion, the second printed circuit board connection portion, the first socket connection portion, and the second socket connection portion of the structure.

14. The system of claim 13, wherein the printed circuit board comprises a first surface and a second surface opposite to the first surface, the structure attached to the first surface of the printed circuit board, the system further comprising a socket attached to the second surface of printed circuit board at a plurality of conductive contacts, at least one of the plurality of conductive contacts electrically conductively coupled to the structure via one or more interconnect traces and one or more vias in the printed circuit board.

15. The system of claim 14, wherein the one or more interconnect traces are one or more first interconnect traces and the one or more vias are one or more first vias, the system further comprising a voltage regulator attached to the second surface of the printed circuit board, the voltage regulator electrically conductively coupled to the structure by one or more second interconnect traces and one or more second vias in the printed circuit board.

16. The system of claim 13, further comprising:
a socket attached to the printed circuit board; and
an integrated circuit component attached to the socket.

17. The system of claim 13, wherein the backplate further comprises one or more reinforcement features.

18. An apparatus comprising:
a printed circuit board;
a socket attached to the printed circuit board;
an integrated circuit component attached to the socket;
a voltage regulator attached to the printed circuit board;
a power supply delivery means for providing a power supply signal from the voltage regulator to the integrated circuit component; and
a reinforcement means for providing structural integrity to the apparatus, the reinforcement means attached to the printed circuit board.

19. The apparatus of claim 18, wherein the printed circuit board comprises a first surface and a second surface opposite to the first surface, the power supply delivery means attached to the first surface of the printed circuit board, the apparatus further comprising a socket attached to the second surface of printed circuit board at a plurality of conductive contacts, at least one of the plurality of conductive contacts electrically conductively coupled to the power supply delivery means via one or more interconnect traces and one or more vias in the printed circuit board.

20. The apparatus of claim 19, wherein the one or more interconnect traces are one or more first interconnect traces and the one or more vias are one or more first vias, the apparatus further comprising a voltage regulator attached to the second surface of the printed circuit board, the voltage regulator electrically conductively coupled to the power supply delivery means by one or more second interconnect traces and one or more second vias in the printed circuit board.
